(19) United States
(12) Patent Application Publication
(10) Pub. No.: US 2025/0282134 A1
(43) Pub. Date: Sep. 11, 2025

(54) SEPARATING METHOD AND SEPARATING SYSTEM

(71) Applicant: Tokyo Electron Limited, Tokyo (JP)

(72) Inventors: Kei TASHIRO, Koshi City (JP); Katsuhiro IINO, Koshi City (JP)

(73) Assignee: Tokyo Electron Limited, Tokyo (JP)

(21) Appl. No.: 19/069,254

(22) Filed: Mar. 4, 2025

(30) Foreign Application Priority Data
Mar. 5, 2024 (JP) 2024-032810
Nov. 21, 2024 (JP) 2024-203131

(51) Int. Cl. B32B 43/00

(52) U.S. Cl. CPC B32B 43/006; B32B 2457/14

(57) ABSTRACT

A method of separating a second substrate from a combined structure in which a first substrate and the second substrate are bonded to each other via an adhesive layer is provided. The second substrate allows light to pass therethrough and the adhesive layer is degraded by absorbing the light. The separating method includes radiating the light to the adhesive layer via the second substrate to form, at an interface between the adhesive layer and the second substrate, a first separation region by degrading the adhesive layer that absorbs the light and a second separation region extending from the first separation region at least in a radial direction of the adhesive layer; and separating the second substrate from the combined structure.

### CROSS-REFERENCE TO RELATED APPLICATIONS

This application claims the benefit of Japanese Patent Application No. 2024-032810 filed on Mar. 5, 2024 and Japanese Patent Application No. 2024-203131 filed on Nov. 21, 2024, the entire disclosures of which are incorporated herein by reference.

### TECHNICAL FIELD

The exemplary embodiments described herein pertain generally to a separating method and a separating system.

### BACKGROUND

Patent Document 1 discloses a member separating method for separating first and second members which are bonded to each other by an adhesive layer. This member separating method includes a process of radiating a laser beam to a photothermal conversion layer provided on a first main surface of the first member and a process of separating the first member from the second member by applying a force to the first member and the second member.

### PRIOR ART DOCUMENT

Patent Document 1: Japanese Patent Laid-open Publication No. 2015-122370

### SUMMARY

In an exemplary embodiment, there is provided a method of separating a second substrate from a combined structure in which a first substrate and the second substrate are bonded to each other via an adhesive layer, the second substrate allows light to pass therethrough, and the adhesive layer is degraded by absorbing the light, the method including radiating the light to the adhesive layer via the second substrate to form, at an interface between the adhesive layer and the second substrate, a first separation region by degrading the adhesive layer that absorbs the light and a second separation region extending from the first separation region at least in a radial direction of the adhesive layer; and separating the second substrate from the combined structure.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a schematic plan view illustrating a configuration of a separating system according to the present exemplary embodiment;

FIG. 2 is a schematic side view illustrating a configuration of a combined wafer;

FIG. 3 is a schematic plan view illustrating a configuration of a first wafer;

FIG. 4 is a schematic side view illustrating a configuration of a laser radiation device;

FIG. 5 is a schematic plan view illustrating the configuration of the laser radiation device;

FIG. 6 is a diagram illustrating a schematic configuration of a laser head;

FIG. 7 is a flowchart illustrating main processes of a separating processing;

FIG. 8 is a diagram illustrating a state in which a first separation region and a second separation region are formed;

FIG. 9 is a diagram illustrating a schematic configuration of the first separation region and the second separation region;

FIG. 10 is a diagram illustrating the schematic configuration of the first separation region and the second separation region;

FIG. 11 is a diagram illustrating an example of a state in which adhesive powder flows out;

FIG. 12 is a diagram illustrating the schematic configuration of the first separation region and the second separation region;

FIG. 13A to FIG. 13C are diagrams illustrating a state in which a first wafer and a second wafer are separated from each other;

FIG. 14 is a diagram illustrating the schematic configuration of the first separation region and the second separation region in a first pattern;

FIG. 15 is a diagram illustrating the schematic configuration of the first separation region and the second separation region in a second pattern;

FIG. 16 is a diagram illustrating the schematic configuration of the first separation region and the second separation region in a third pattern;

FIG. 17 is a diagram illustrating the schematic configuration of the first separation region and the second separation region in a fourth pattern;

FIG. 18 is a diagram illustrating the schematic configuration of the first separation region and the second separation region in a fifth pattern;

FIG. 19 is a diagram illustrating the schematic configuration of the first separation region and the second separation region in a sixth pattern;

FIG. 20 is a diagram illustrating the schematic configuration of the first separation region and the second separation region in a seventh pattern;

FIG. 21 is a diagram illustrating the schematic configuration of the first separation region and the second separation region in an eighth pattern;

FIG. 22 is a diagram illustrating the schematic configuration of the first separation region and the second separation region in a ninth pattern;

FIG. 23 is a diagram illustrating the schematic configuration of the first separation region and the second separation region in a tenth pattern;

FIG. 24 is a schematic plan view illustrating a configuration of a gas injection device;

FIG. 25A to FIG. 25D are diagrams illustrating a state in which a first wafer and a second wafer are separated from each other according to another exemplary embodiment; and

FIG. 26A to FIG. 26D are diagrams illustrating a state in which a first wafer and a second wafer are separated from each other according to another exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

The following exemplary embodiments are examples for describing the present disclosure, and the present disclosure is not limited thereto. In the following description, same parts or parts having same function will be assigned same reference numerals, and redundant description will be omitted.

Recently, the thinning of semiconductor devices has been increasingly demanded. In a manufacturing process of a semiconductor device, for example, in a TSV (Through-Silicon Via) process and a Fan-Out process, a semiconductor wafer (hereinafter, referred to as “wafer”) with device layers, such as a plurality of circuits, thereon is thinned. If the thinned wafer is transferred or subjected to a subsequent processing, such as a photolithography processing as it is, bending or crack may occur in the wafer. Therefore, in order to reinforce the wafer, the wafer is bonded to a support wafer with, for example, a bonding layer therebetween. Then, the subsequent processing is performed on the wafer in the state where the wafer is bonded to the support wafer as described above, and subsequently, the wafer and the support wafer are separated from each other.

To separate the wafer and the support wafer, various methods have been used conventionally. The main separating methods include, for example, a method of applying a force to the wafer and the support wafer to separate them and a method of radiating a laser beam to the bonding layer to separate the wafer and the support wafer. In the following description, the former separating method may be referred to as “mechanical separation”, and the latter method as “laser separation”.

In the mechanical separation, for example, a blade is inserted into a bonding interface between the wafer and the support wafer to separate the support wafer from the wafer. In this method, before the separation, the wafer needs to be thinned and the like in a state where the wafer and the support wafer are bonded to each other. Thus, sufficient bonding strength is required to withstand these processings. In other words, during the separation, a predetermined high force (hereinafter, referred to as “separation force”) needs to be applied. In this case, a load applied to the wafer increases, and, thus, the wafer may be cracked. To suppress these cracks in the wafer, it has been considered to insert blades into a plurality of locations along the circumferential direction of the bonded wafers to expand a portion serving as a separation start point. However, in this case, the inserting of blades into the plurality of locations increases the processing time, which may cause a reduction in productivity. Also, the use of blades involves challenges in selecting and adjusting the blades, and maintenance becomes cumbersome due to blade abrasion. Further, in some cases, a plurality of bonding layers for bonding the wafer and the support wafer may be required, and in such cases, it takes time to clean and remove the bonding layers after the separation.

In the laser separation described in Patent Document 1, a photothermal conversion layer to which a laser beam is radiated during separation is provided in addition to an adhesive layer as a bonding layer for bonding the wafer and the support wafer. Since the photothermal conversion layer is unnecessary from the viewpoint of adhesiveness in the bonding layer, there is room for improvement in terms of productivity by omitting the process of forming the photothermal conversion layer.

The technique according to the present disclosure efficiently separates a second substrate from a combined structure in which a first substrate and the second substrate are bonded to each other with an adhesive layer therebetween. Hereinafter, a separating system and a separating method according to the present exemplary embodiment will be described with reference to the accompanying drawings. The same reference numerals will be given to elements having substantially the same functional configurations throughout the specification and the drawings, and redundant description thereof will be omitted.

### <Configuration of Separating System>

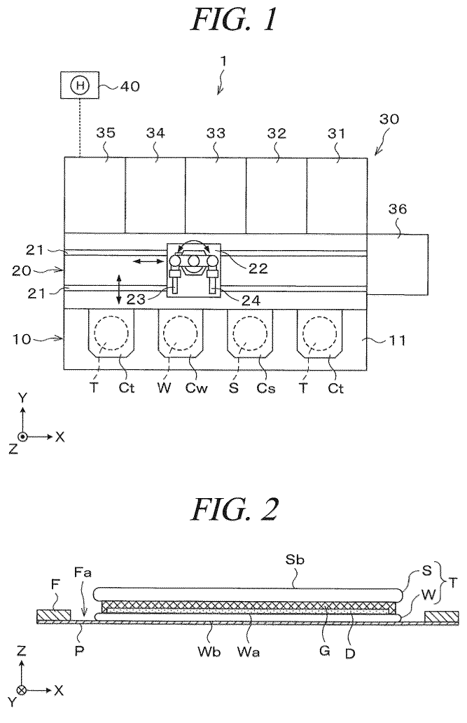

First, a configuration of a separating system according to the present exemplary embodiment will be described. FIG. 1 is a schematic plan view illustrating a configuration of a separating system 1. Hereinafter, to clarify positional relationships, the X-axis, the Y-axis and the Z-axis directions which are orthogonal to each other will be defined. The positive Z-axis direction will be regarded as a vertically upward direction.

As shown in FIG. 2, the separating system 1 separates a second wafer S from a combined wafer T in which a first wafer W and the second substrate S are bonded to each other with an adhesive G therebetween. Herein, the first wafer W corresponds to the first substrate in the present disclosure, the second wafer S corresponds to the second substrate in the present disclosure, the adhesive G corresponds to the adhesive layer in the present disclosure, and the combined wafer T corresponds to the combined structure in the present disclosure. Also, the adhesive G is formed of a single layer.

Hereinafter, in the first wafer W, a surface bonded to the second wafer S with the adhesive G therebetween will be referred to as a front surface Wa, and a surface opposite to the front surface Wa will be referred to as a rear surface Wb. Likewise, in the second wafer S, a surface bonded to the first wafer W with the adhesive G therebetween will be referred to as a front surface Sa, and a surface opposite to the front surface Sa will be referred to as a rear surface Sb.

As shown in FIG. 2, the first wafer W is a semiconductor wafer, such as a silicon substrate, and has a device layer D including a plurality of circuits on the front surface Wa. The first wafer W is thinned by polishing, for example, the rear surface Wb.

The combined wafer T is fixed to a dicing frame F with a dicing tape P therebetween. Specifically, the combined wafer T is located in an opening Fa of the dicing frame F, and the dicing tape P is attached to the rear surface Wb of the first wafer W and a rear surface of the dicing frame F so as to close the opening Fa from the rear surface. Thus, the combined wafer T is fixed to (or held by) the dicing frame F.

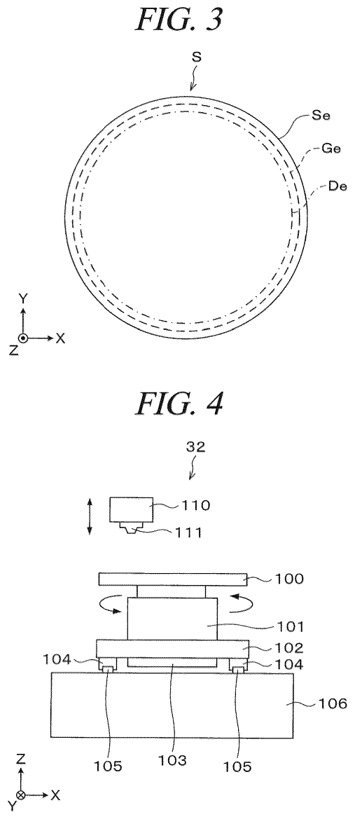

As shown in FIG. 3, a peripheral edge Ge of the adhesive G is located inside a peripheral edge Se of the second wafer S when viewed from the top. In an exemplary embodiment, the adhesive G located outside the peripheral edge Se of the second wafer S has been removed previously. Also, the peripheral edge Ge of the adhesive G is located outside a peripheral edge De of the device layer D when viewed from the top.

The second wafer S serves to support the first wafer W. The second wafer S may be formed of a material, for example, a silicon wafer, through which infrared light having a predetermined wavelength can pass.

The adhesive G attaches the first wafer W to the second wafer S and is degraded by absorbing infrared light having a predetermined wavelength and integral intensity. Herein, the term “degradation” refers to a state in which the adhesive G can be broken with a slight external force or a state in which its adhesiveness to a layer in contact with the adhesive G is reduced. That is, when the adhesive G absorbs infrared light, the radiated portion of the adhesive G softens and loses its bonding strength (adhesiveness) that existed before the radiation of infrared light. In an exemplary embodiment, when the adhesive G absorbs infrared light, it is heated by energy of the absorbed infrared light to be melted (ablated) and also carbonized. In an exemplary embodiment, the adhesive G, which has been degraded by absorbing the infrared light, generates adhesive powder Gp, which will be described later, as a by-product.

As shown in FIG. 1, the separating system 1 has a configuration in which a carry-in/out station 10, a transfer station 20, and a processing station 30 are connected as one body. Cassettes Cw, Cs and Ct configured to accommodate a plurality of first wafers W, a plurality of second wafers S, and a plurality of combined wafers T, respectively, are carried in and out between the carry-in/out station 10 and, for example, the outside. The transfer station 20 transfers the first wafer W, the second wafer S, the combined wafer T between the carry-in/out station 10 and the processing station 30. The processing station 30 includes various processing devices which perform predetermined processings on the first wafer W, the second wafer S, the combined wafer T.

A cassette stage 11 is provided in the carry-in/out station 10. In the illustrated example, a plurality of, for example, four cassettes Cw, Cs and Ct can be placed in a row in the X-axis direction on the cassette stage 11. In the present exemplary embodiment, the cassette Ct placed in the negative X-axis direction is used as a loader cassette configured to accommodate an unprocessed combined wafer T, and the cassettes Cw and Cs placed at the center of the carry-in/out station 10 in the X-axis direction are used as unloader cassettes configured to accommodate processed (separated) first and second wafers W and S. Also, the cassette Ct placed in the positive X-axis direction is used as an unloader cassette configured to collect and accommodate a combined wafer T which has a problem during processing. The number of cassettes Cw, Cs and Ct placed on the cassette stage 11 is not limited to the example of the present exemplary embodiment, but can be arbitrarily determined.

The transfer station 20 is provided adjacent to the carry-in/out station 10. The transfer station 20 is equipped with a wafer transfer device 22 configured to be movable on a transfer path 21 which is elongated in the X-axis direction. The wafer transfer device 22 has, for example, two transfer arms 23 and 24. A first transfer arm 23 serves to transfer a dicing frame, and transfers the combined wafer T fixed to the dicing frame F or the first wafer W. A second transfer arm 24 serves to transfer a wafer, and transfers the separated second wafer S. Each of the transfer arms 23 and 24 is configured to be movable in a horizontal direction and a vertical direction and pivotable around a horizontal axis and a vertical axis. However, the configuration of the transfer arms 23 and 24 is not limited to the example of the present exemplary embodiment, and various other configurations may be adopted.

The processing station 30 is provided adjacent to the transfer station 20. The processing station 30 is equipped with, in the positive Y-axis direction of the transfer station 20, an alignment device 31, a laser radiation device 32 serving as a light radiation device, a separating device 33, a first cleaning device 34, and a second cleaning device 35, which are placed and arranged from the positive X-axis direction toward the negative X-axis direction. Also, the processing station 30 is equipped with an inverting device 36 placed in the positive X-axis direction of the transfer station 20. Further, the number and the layout of these devices 31 to 36 are not limited to the example of the present exemplary embodiment, but can be arbitrarily determined.

In the alignment device 31, for example, an infrared (IR) camera is used to detect a pattern of the first wafer W, i.e., a pattern of a die Wd and a scribe line Ws, and adjust a position of the combined wafer T. The alignment device 31 also serves as a detection device of the present disclosure to detect the pattern. Further, a commonly known device may be used as the alignment device 31.

The laser radiation device 32 is configured to radiate infrared light Lir, which is a laser beam, to the adhesive G via the second wafer S. A configuration of the laser radiation device 32 will be described later.

The separating device 33 is configured to apply a force to the combined wafer T to separate the second wafer S from the combined wafer T. Specifically, the separating device 33 inserts a blade into one end of a bonding interface between the first wafer W and the second wafer S, and then separates the second wafer S from the first wafer W in a direction from the one end toward the other end. A configuration of the separating device 33 will be described later.

The first cleaning device 34 is configured to remove the adhesive G from the front surface Wa of the separated first wafer W which has been fixed to the dicing frame F, and cleans the front surface Wa by spinning. A commonly known device may be used as the first cleaning device 34.

The second cleaning device 35 is configured to remove the adhesive G from the front surface Sa of the separated second wafer S, and cleans the front surface Sa by spinning. A commonly known device may be used as the second cleaning device 35.

The inverting device 36 is configured to invert the front surface and the rear surface of the separated second wafer S. A commonly known device may be used as the inverting device 36.

The separating system 1 is equipped with at least one control device 40 as shown in FIG. 1. The control device 40 processes computer-executable commands that cause the separating system 1 to execute various processes described in the present disclosure. The control device 40 may be configured to control each component of the separating system 1 to perform various processes including the separating processing described in the present disclosure. In an exemplary embodiment, a part or all of the control device 40 may be included in the separating system 1. The control device 40 may include a processor, a storage unit, and a communication interface. The control device 40 is implemented by, for example, a computer. The processor may be configured to perform various control operations by reading a program, which provides a logic or routine making it possible to perform various control operations, from the storage unit and executing the read program. This program may be prestored in the storage unit or may be acquired through a medium when necessary. The acquired program is stored in the storage unit, and read from the storage and executed by the processor. The medium may be one of various computer-readable storage media or may be a communication line connected to the communication interface. The storage medium may be a transitory one or a non-transitory one. The processor may be a central processing unit (CPU), or may include one or more circuits. The storage unit may include a random access memory (RAM), a read only memory (ROM), a hard disk drive (HDD), a solid state drive (SSD), or a combination thereof. The communication interface may communicate with the separating system 1 via a communication line, such as a local area network (LAN).

The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry is hardware that carries out or is programmed to perform the recited functionality. The hardware may be any hardware disclosed herein which is programmed or configured to carry out the recited functionality.

There is a memory that stores a computer program which includes computer instructions. These computer instructions provide the logic and routines that enable the hardware (e.g., processing circuitry or circuitry) to perform the method disclosed herein. This computer program can be implemented in known formats like a computer-readable storage medium, a computer program product, a memory device, a record medium such as a CD-ROM or DVD, and/or the memory of a FPGA or ASIC.

### <Configuration of Laser Radiation Device>

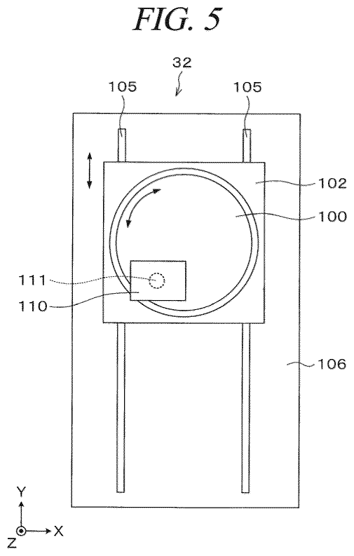

Hereinafter, the laser radiation device 32 will be described. FIG. 4 is a schematic side view illustrating a configuration of the laser radiation device 32. FIG. 5 is a schematic plan view illustrating the configuration of the laser radiation device 32.

The laser radiation device 32 includes a chuck 100 configured to hold the combined wafer T on an upper surface thereof. The chuck 100 is configured to attract and hold the combined wafer T fixed to the dicing frame F. The chuck 100 is supported by a slider table 102 with an air bearing 101 therebetween. A rotating mechanism 103 is provided on a lower surface of the slider table 102. The rotating mechanism 103 incorporates therein, for example, a motor as a driving source. The chuck 100 is configured to be rotated about a 0 axis (vertical axis) by the rotating mechanism 103 via the air bearing 101 therebetween. The slider table 102 is configured to be moved by a moving mechanism 104, which is provided on the lower surface side thereof, along a rail 105 which is provided on a base 106 and elongated in the Y-axis direction. Further, a driving source of the moving mechanism 104 may be, by way of non-limiting example, a linear motor.

A laser head 110 serving as an infrared light radiation device is provided above the chuck 100. The laser head 110 includes a lens 111. The lens 111 is a cylindrical member provided on a lower surface of the laser head 110, and is configured to radiate a laser beam to the combined wafer T held by the chuck 100. In the present exemplary embodiment, the laser beam is the infrared light Lir, and the infrared light Lir emitted from the laser head 110 passes through the second wafer S so as to be radiated to the adhesive G.

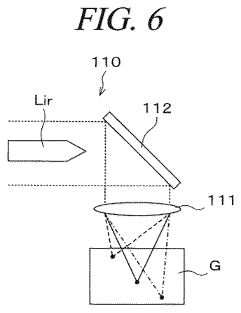

For example, a galvano mirror is used for the laser head 110. A plurality of galvano mirrors 112 is arranged inside the laser head 110 as shown in FIG. 6. Further, an f-θ lens is used for the lens 111. With this configuration, the infrared light Lir input to the laser head 110 is reflected by the galvano mirrors 112, propagated to the lens 111, and radiated to the adhesive G via the second wafer S. Furthermore, the adhesive G may be scanned with the infrared light Lir by adjusting an angle of the galvano mirrors 112.

Moreover, the laser head 110 is configured to be movable up and down by an elevating mechanism (not shown).

### <Operation of Separating System>

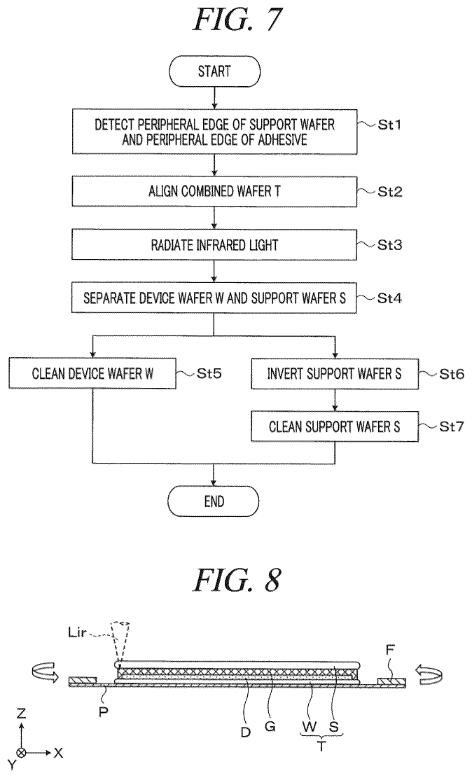

Hereinafter, a separating processing performed by the separating system 1 configured as described above will be described. FIG. 7 is a flowchart illustrating main processes of a separating processing.

First, the cassette Ct accommodating therein the plurality of combined wafers T is placed on the cassette stage 11 of the carry-in/out station 10. Herein, the combined wafer T is fixed to the dicing frame F.

Then, the combined wafer T in the cassette Ct is taken out by the first transfer arm 23 of the wafer transfer device 22 and transferred to the alignment device 31. In the alignment device 31, for example, the IR camera is used to detect the peripheral edge Se of the second wafer S and the peripheral edge Ge of the adhesive G (process St1 in FIG. 7). Also, when the adhesive G is formed, the alignment device 31 stores a relative position of the peripheral edge Ge of the adhesive G with respect to the peripheral edge Se of the second wafer S, and reads the position at the process St1. In this case, the alignment device 31 detects only the peripheral edge Se of the second wafer S at the process St1, and estimates the peripheral edge Ge of the adhesive G based on the read relative position with respect to the peripheral edge Se of the second wafer S. In the exemplary embodiment, the alignment device 31 may also detect the peripheral edge De of the device layer D at the process St1.

Then, the alignment device 31 performs position adjustment (alignment) of the combined wafer T based on the result of detecting the peripheral edge Se of the second wafer S and the peripheral edge Ge of the adhesive G (process St2 in FIG. 7).

Thereafter, the combined wafer T is transferred to the laser radiation device 32 by the first transfer arm 23 of the wafer transfer device 22. The combined wafer T carried into the laser radiation device 32 is held by the chuck 100 and moved to a processing position by the moving mechanism 104. In this case, eccentricity control of the combined wafer T and position adjustment in the circumferential direction are performed based on the result of detecting the peripheral edge Se of the second wafer S and the peripheral edge Ge of the adhesive G at the process St1.

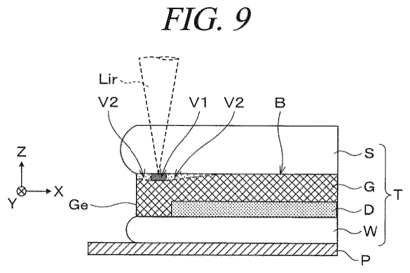

Then, as shown in FIG. 8 and FIG. 9, the laser radiation device 32 radiates the infrared light Lir from the laser head 110 in the circumferential direction of the adhesive G while the combined wafer T is rotated by the rotating mechanism 103 (process St3 in FIG. 7). In the present exemplary embodiment, the infrared light Lir is radiated concentrically with respect to the adhesive G over one round of the entire circumference of the adhesive G in the circumferential direction. Further, in the present exemplary embodiment, the infrared light Lir is radiated to the adhesive G at an interface B between the front surface Sa of the second wafer S and the adhesive G outside the peripheral edge De of the device layer D in a radial direction. Also, the infrared light Lir is radiated to a position inwardly spaced apart in the radial direction from the peripheral edge Ge of the adhesive G.

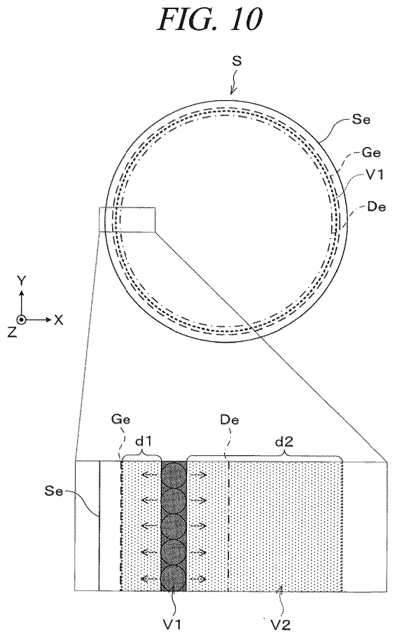

Further, the infrared light Lir is radiated in a pulse shape as shown in a plurality of circles of FIG. 10, and a first separation region V1 is formed at the radiation position. A plurality of radiation positions of the infrared light in the pulse shape is continuous in a strip shape, and forms a single first separation region V1. In the first separation region V1, the adhesive G is degraded by absorbing the infrared light Lir having a predetermined wavelength and integral intensity. Thus, the adhesiveness of the adhesive G is reduced at the interface B between the front surface Sa of the second wafer S and the adhesive G. In the exemplary embodiment, the front surface Sa of the second wafer S and the adhesive G are separated and spaced apart from each other in the first separation region V1. In the exemplary embodiment, the infrared light Lir is radiated not in the pulse shape but in a continuous manner, and forms the first separation region V1 which is continuously formed in the adhesive G.

As shown in FIG. 9 and FIG. 10, a second separation region V2 extends from the first separation region V1 in at least the radial direction (a dotted arrow direction in FIG. 10) of the adhesive G at the interface B between the front surface Sa of the second wafer S and the adhesive G. In the present exemplary embodiment, the second separation region V2 extends to the peripheral edge Ge of the adhesive G outside the first separation region V1 in the radial direction in the adhesive G, and further extends to the inside of the peripheral edge De of the device layer D in the radial direction. In the exemplary embodiment, the front surface Sa of the second wafer S and the adhesive G are separated and spaced apart from each other in the second separation region V2.

In the exemplary embodiment, the infrared light Lir is radiated in the pulse shape, and, thus, the second separation region V2 is elongated omnidirectionally from the first separation region V1 formed in each of the plurality of circles shown in FIG. 10. Further, the second separation regions V2 respectively elongated from the plurality of first separation regions V1 overlap to be continuous in a strip shape, and, thus, a single second separation region V2 is formed.

In the exemplary embodiment, the adhesive at a portion of the second separation region V2 is softened by the heat which is generated when the adhesive G in the first separation region V1 absorbs the infrared light and transmitted to the surroundings. Thus, the adhesive loses its bonding strength (adhesiveness) that existed before the radiation of the infrared light Lir. For example, the second separation region V2 is formed when the adhesive G is melted by the heat transmitted from the first separation region V1 and carbonized.

In the exemplary embodiment, the second separation region V2 is formed by a stress generated between the front surface Sa of the second wafer S and the adhesive G in a direction away from each other due to expansion or contraction of the adhesive G irradiated with the infrared light Lir in the first separation region V1.

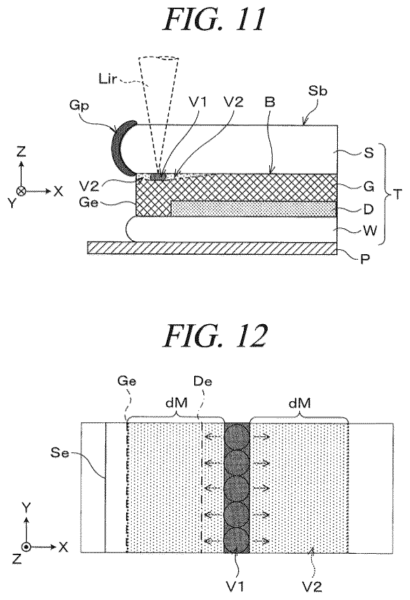

In this regard, as a result of the earnest research conducted by the present inventors, it was found that when a width d1 of the second separation region V2 extending in the radial direction to the outside from the first separation region is too small, the adhesive powder Gp degraded from the adhesive G by the absorbed infrared light Lir may flow out from the peripheral edge Ge of the adhesive G as shown in FIG. 11. The adhesive powder Gp adheres to, for example, the peripheral edge Se or the rear surface Sb of the second wafer S. When the adhesive powder Gp flows out, it may cause contamination within the laser radiation device 32 and contamination of the second transfer arm 24 of the wafer transfer device 22 that transfers the second wafer S.

In this regard, the flow of the adhesive powder Gp to the outside from the peripheral edge Ge of the adhesive G may be suppressed by increasing the width d1 of the second separation region V2 extending in the radial direction to the outside from the first separation region.

In the exemplary embodiment, from the viewpoint of increasing the width d1 of the second separation region V2, a maximum width dM in the radial direction of the second separation region V2 extending from the first separation region V1 is previously acquired by experiment or simulation when the infrared light Lir having a predetermined wavelength and integral intensity is radiated. For example, the second separation region V2 extending in the radial direction to the inside from the first separation region V1 as shown in FIG. 10 can be estimated to have a width d2 equal to the maximum width dM if there is no factor that causes interruption of extension in the extension direction. In this case, it is assumed that the second separation region V2 extending in the radial direction to the outside from the first separation region V1 has extended to its maximum width dM unless it reaches the peripheral edge Ge of the adhesive G.

Since the maximum width dM in the radial direction of the second separation region V2 extending from the first separation region V1 is acquired when the infrared light Lir having a predetermined wavelength and integral intensity is radiated, a desirable radiation position of the infrared light Lir can be determined. For example, as shown in FIG. 12, a radiation position of the infrared light Lir is determined such that the distance from the peripheral edge Ge of the adhesive G to the radiation position of the infrared light Lir, more specifically to an outer radial end of the first separation region V1 formed by radiating the infrared light Lir, becomes equal to the maximum width dM. Therefore, when the second separation region V2 is extended to the maximum width dM to the outside in the radial direction of the first separation region V1, the second separation region V2 reaches the peripheral edge Ge of the adhesive G. The radiation position of the infrared light Lir is determined in this way, and, thus, the width d1 of the second separation region V2 outwardly in the radial direction of the adhesive G can be increased. As a result, it is possible to suppress the flow of the adhesive powder Gp to the outside from the peripheral edge Ge of the adhesive G.

In the exemplary embodiment, from the viewpoint of increasing the width d1 of the second separation region V2 outwardly in the radial direction of the adhesive G, the infrared light Lir is radiated to the inside of the peripheral edge De of the device layer D in the radial direction as shown in FIG. 12.

In other words, the sum of lengths of the first separation region V1 and the second separation region V2 in the radial direction can be increased by increasing the width d1 of the second separation region V2 outwardly in the radial direction of the adhesive G. Also, by increasing the sum of lengths of the first separation region V1 and the second separation region V2, the overall adhesiveness of the adhesive G can be reduced. Therefore, a processing can be performed appropriately during the separation of the second wafer S in the separating device 33 to be described later. Further, a part of the first separation region V1 and the second separation region V2 can be used as a separation start portion M2 in the separating method according to another exemplary embodiment to be described later.

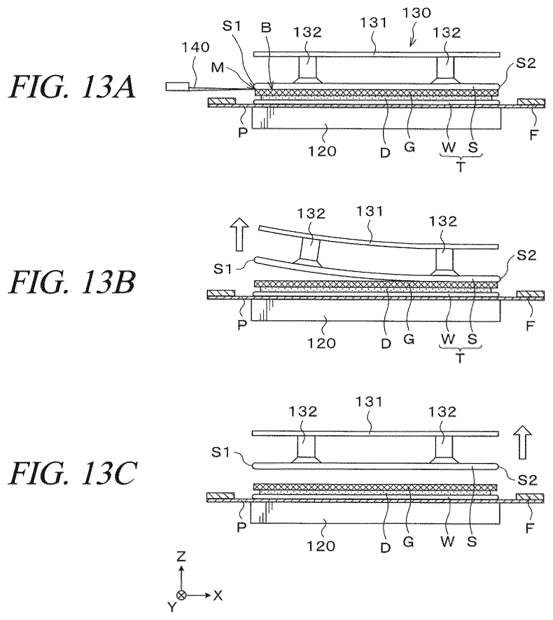

Then, the combined wafer T is transferred to the separating device 33 by the first transfer arm 23 of the wafer transfer device 22. The separating device 33 applies a force to the combined wafer T to separate the combined wafer T into the first wafer W and the second wafer S (St4 in FIG. 7). FIG. 13A to FIG. 13C are diagrams illustrating a state in which the first wafer W and the second wafer S are separated from each other.

First, as shown in FIG. 13A, a first holder 120 attracts and holds the entire surface of the first wafer W via the dicing tape P and a second holder 130 attracts and holds the second wafer S. The second holder 130 is equipped with a deformable thin plate-shaped elastic member 131 and a plurality of suction devices 132 configured to attract and hold the second wafer S. Further, the layout and the number of suction devices 132 can be arbitrarily determined. Furthermore, instead of the plurality of suction devices 132, other suction devices that can be deformed and can attract and hold the entire surface of the second wafer S may be used.

Then, as shown in FIG. 13B, a blade 140 is inserted into the bonding interface between the first wafer W and the second wafer S. In the present exemplary embodiment, the blade 140 is inserted into the interface B between the second wafer S and the adhesive G at which the first separation region V1 or the second separation region V2 is formed. Further, when the blade 140 is moved further forward, a separation start portion M serving as a separation start point is formed on a side surface on one end S1's side between the second wafer S and the adhesive G. The separation of the second wafer S starts from the separation start portion M. Also, the number of blades 140 may be more than one.

Herein, as described above, in the process St3, the adhesive G protruding sideways from the combined wafer T has been removed. If the adhesive G protrudes sideways from the combined wafer T, the blade 140 is not inserted into the appropriate position, and, thus, the separation start portion M may not be formed. Therefore, by performing the process St3 as in the present exemplary embodiment, the blade 140 can be inserted stably.

Since the first separation region V1 and the second separation region V2 are formed in the process St3, a load (hereinafter, referred to as “blade force”) applied to the blade 140 can be reduced when the blade 140 is inserted into the peripheral edge Ge of the adhesive G. From such a viewpoint, it is desirable to increase a total sum of lengths of the first separation region V1 and the second separation region V2 in the radial direction. Thus, it is possible to further reduce the blade force.

Thereafter, as shown in FIG. 13B, the suction device 132 on the one end S1's side is raised, and the separation of the second wafer S starts from the separation start portion M in a direction from the one end S1 toward the other end S2. Then, as shown in FIG. 13C, the suction device on the other end S2's side is also raised, and the entire surface of the second wafer S is separated from the first wafer W. Since the bonding strength between the first wafer W and the second wafer S has been reduced by degrading the adhesive G in the process St3, the second wafer S can be separated from the first wafer W with a small separation force. From such a viewpoint, it is desirable to increase the total sum of lengths of the first separation region V1 and the second separation region V2 in the radial direction. Thus, it is possible to reduce a load (hereinafter, referred to as “peeling force”) applied when the suction device 132 is raised.

Thereafter, the separated first wafer W is transferred to the first cleaning device 34 by the first transfer arm 23 of the wafer transfer device 22. The first cleaning device 34 removes the adhesive G remaining on the first wafer W, and cleans the front surface Wa by spinning (process St5 in FIG. 7). Since the adhesive G is degraded in the process St5, it is possible to easily perform cleaning. For this reason, it is possible to shorten the cleaning time as compared to a case where the adhesive G is not degraded according to the conventional techniques. Also, it is possible to reduce an amount of a cleaning solution consumed in the spin cleaning.

Then, the first wafer W after being subjected to all the necessary processings is transferred to the cassette Cw of the cassette stage 11 by the first transfer arm 23 of the wafer transfer device 22.

In parallel with the process St5 on the separated first wafer W, a required processing is performed on the separated second wafer S.

That is, the separated second wafer S is transferred to the inverting device 36 by the second transfer arm 24 of the wafer transfer device 22. The inverting device 36 inverts the front surface and the rear surface of the second wafer S (process St6 in FIG. 7).

Thereafter, the second wafer S is transferred to the second cleaning device 35 by the second transfer arm 24 of the wafer transfer device 22. The second cleaning device 35 removes the adhesive G remaining on the second wafer S, and cleans the front surface Sa by spinning (process St7 in FIG. 7).

Then, the second wafer S after being subjected to all the necessary processings is transferred to the cassette Cs of the cassette stage 11 by the second transfer arm 24 of the wafer transfer device 22. As a result, a series of separating processings in the separating system 1 is completed.

According to the above-described exemplary embodiments, it is possible to appropriately and efficiently separate the second wafer S from the combined wafer T.

That is, it is possible to overcome the disadvantages of the mechanical separation. According to the present exemplary embodiment, the load applied to the separating device 33 and the first wafer W can be reduced by decreasing the separation force, such as the blade force or the peeling force, in the process St4. Since only a small separation force is required, it is not necessary to insert the blades 140 into the plurality of locations along the circumferential direction. Thus, the processing time can be reduced and the productivity can be improved. Further, since the number of insertions of the blade 140 can be reduced, it is possible to suppress scratches on the second wafer S and the first wafer W caused by contacts with the blade 140. Also, it is easy to select and adjust the blade 140, and it is possible to reduce the maintenance frequency by suppressing the consumption of the blade 140. Further, in the present exemplary embodiment, the adhesive G is formed of a single layer. Thus, after the separation, the adhesive G can be removed quickly through the cleaning.

Also, it is possible to overcome the disadvantages of the radiation of the infrared light Lir. In the present exemplary embodiment, the infrared light Lir is radiated to the entire circumference of the adhesive G, and the first separation region V1 and the second separation region V2 are formed in the entire circumference. Thus, the adhesiveness of the adhesive G to the entire surface thereof can be reduced. Therefore, it is possible to reduce the peeling force in the process St4. In the exemplary embodiment, the infrared light Lir is radiated to the outside of the peripheral edge De of the device layer D in the radial direction. Thus, the device layer D cannot be damaged. Even if the infrared light Lir is radiated to the outside of the peripheral edge De of the device layer D in the radial direction, the second separation region V2 extends to the inside of the peripheral edge De of the device layer D in the radial direction. Thus, it is possible to reduce the blade force and the peeling force in the process St4. In another exemplary embodiment, the infrared light Lir is radiated to a position inwardly spaced apart in the radial direction by the maximum width dM from the peripheral edge Ge of the adhesive G, and the first separation region V1 is formed. Thus, it is possible to suppress the flow of the adhesive powder Gp, which may be generated by radiating the infrared light Lir, to the outside from the peripheral edge Ge of the adhesive G. As a result, it is possible to suppress the contamination within the laser radiation device 32 and the contamination of the second transfer arm 24 of the wafer transfer device 22 that transfers the second wafer S. Also, it is possible to suppress the adhesion of the adhesive powder Gp to the rear surface Sb of the second wafer S. Therefore, after the separation of the second wafer S, the adhesive G can be removed quickly through cleaning.

### <Other Exemplary Embodiments of Radiation Pattern of Infrared Light Lir>

In the above-described exemplary embodiment, in the process St3, the infrared light Lir is radiated over one round of the entire circumference of the adhesive G in the circumferential direction, at the position outwardly spaced apart from the peripheral edge De of the device layer D in the radial direction and inwardly spaced apart from the peripheral edge Ge of the adhesive G in the radial direction, to form the first separation region V1. However, the radiation pattern of the infrared light Lir is not limited thereto. Hereinafter, radiation patterns of the infrared light Lir according to other exemplary embodiments will be described.

### (First Pattern)

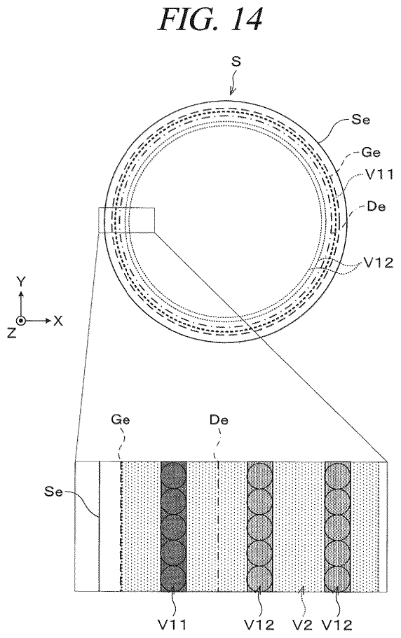

In a first pattern according to another exemplary embodiment, the infrared light Lir having a first intensity is radiated concentrically with respect to the adhesive G toward the adhesive G outwardly spaced apart from the peripheral edge De of the device layer D in the radial direction, and a first separation region V11 is formed as shown in FIG. 14. Further, the infrared light Lir having a second intensity smaller than the first intensity is radiated concentrically with respect to the adhesive G toward the adhesive G overlapping the device layer D when viewed from the top and located inside the peripheral edge De of the device layer D in the radial direction, and another first separation region V12 is formed. However, the number of first separation regions V11 formed outside the peripheral edge De of the device layer D in the radial direction and the number of other first separation region V12 formed inside the peripheral edge De of the device layer D in the radial direction are not limited to the example shown in FIG. 14, and more first separation regions V11 and more first separation region V12 may be formed in the radial direction.

The second intensity refers to an intensity of the infrared light Lir that, when radiated to the adhesive G at the interface B between the front surface Sa of the second wafer S and the adhesive G and overlapping the device layer D when viewed from the top, does not cause damage to the device layer D. The second intensity can be predetermined by experiment or simulation. From the first separation region V11 and the other first separation region V12 of the first pattern, the second separation region V2 is elongated at least in the radial direction of the adhesive G as described above.

According to the first pattern, the infrared light Lir having the first intensity is radiated to a position that does not overlap the device layer D when viewed from the top, and, thus, the adhesiveness of the adhesive G in the first separation region V11 can be sufficiently reduced and the second separation region V2 having a greater width in the radial direction can be formed. A part of the first separation region V1 and the second separation region V2 can be used as the separation start portion M2 in the separating method according to another exemplary embodiment to be described later. Also, the infrared light Lir having the second intensity that does not cause damage to the device layer D is radiated to a position that overlaps the device layer D when viewed from the top, and, thus, the other first separation region V12 and the second separation region V2 that can protect the device layer D and contribute to the reduction in adhesives of the adhesive G can be formed.

### (Second Pattern)

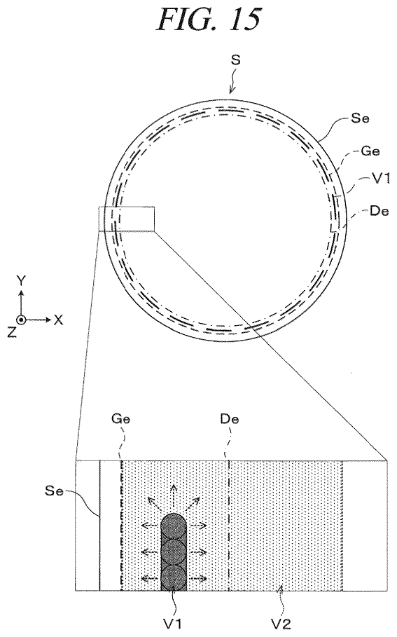

In a second pattern according to another exemplary embodiment, the infrared light Lir is radiated to a plurality of positions spaced apart from each other by a predetermined distance in the circumferential direction of the adhesive G, and the first separation region V1 is formed as shown in FIG. 15. In a portion where the first separation region V1 is not formed in the circumferential direction, the second separation region V2 is elongated and formed and serves to reduce the adhesiveness of the adhesive G in the corresponding portion.

According to the second pattern, the infrared light Lir is not radiated to a predetermined portion, and, thus, the processing time of the laser radiation device 32 is shortened. Also, it is possible to suppress wear of the equipment, such as the laser head 110, caused by the radiation of the infrared light Lir and reduce energy consumption. Therefore, it is possible to reduce costs. Further, it is possible to suppress damage to the combined wafer T caused by the radiation of the infrared light Lir. From such a viewpoint, the infrared light Lir according to the second pattern may be radiated to the inside of the peripheral edge De of the device layer D in the radial direction.

### (Third Pattern)

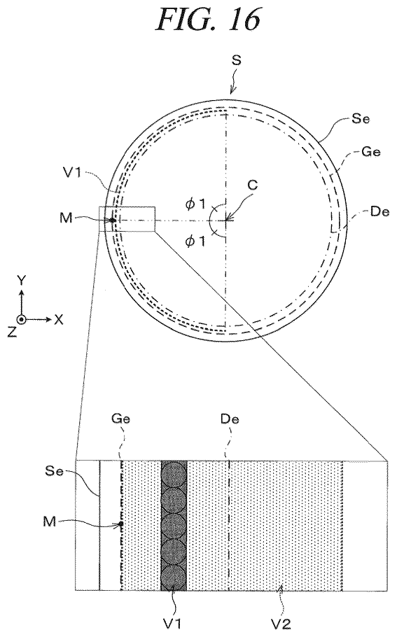

In a third pattern according to another exemplary embodiment, the separation start portion M serving as a separation start point for the separating device 33 in the process St4 is previously determined as shown in FIG. 16. Further, the infrared light Lir is radiated to positions in a circular arc of the concentric circle with respect to the adhesive G where a central angle at a center C of the second wafer S is equal to an angle ϕ1 on both sides of the determined separation start portion M. In the present exemplary embodiment, the angle ϕ1 is 90 degrees.

The third pattern ensures that the first separation region V1 or the second separation region V2 is formed in the separation start portion M serving as the separation start point in the process St4. Thus, it is possible to reduce the blade force. Also, the infrared light Lir is radiated only to a part of the entire circumference of the adhesive G, and, thus, the processing time of the laser radiation device 32 is shortened. Further, it is possible to suppress the wear of the equipment, such as the laser head 110, caused by the radiation of the infrared light Lir and reduce energy consumption. Therefore, it is possible to reduce costs. Furthermore, it is possible to suppress damage to the combined wafer T caused by the radiation of the infrared light Lir.

The upper limit of the angle ϕ1 is not particularly limited, but can be equal to or smaller than 90 degrees from the viewpoint of reduction in costs and suppression of damage to the combined wafer T. The lower limit of the angle ϕ1 is not particularly limited, but can be equal to or greater than 10 degrees from the viewpoint of reduction in blade force.

### (Fourth Pattern)

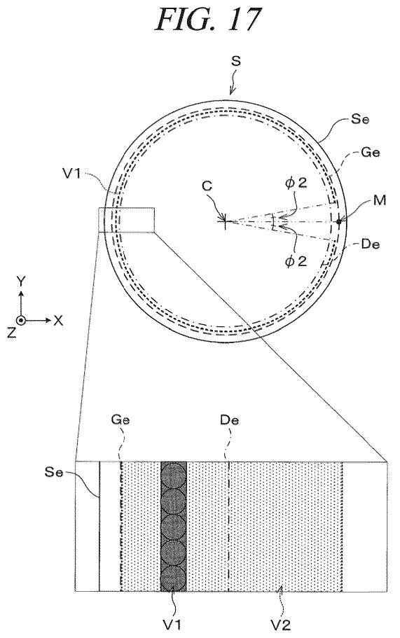

In a fourth pattern according to another exemplary embodiment, the separation start portion M serving as the separation start point for the separating device 33 in the process St4 is previously determined as shown in FIG. 17. Further, the infrared light Lir is radiated to positions in a circular arc of the concentric circle with respect to the adhesive G except a circular arc where the central angle at the center C of the second wafer S is equal to an angle ϕ2 on both sides of the determined separation start portion M. In the present exemplary embodiment, the angle ϕ2 is 20 degrees.

The fourth pattern ensures that the first separation region V1 or the second separation region V2 is not only formed around the separation start portion M serving as the separation start point in the process St4, but formed at other positions. Thus, it is possible to reduce the peeling force.

The upper limit of the angle ϕ2 is not particularly limited, but can be equal to or smaller than 30 degrees from the viewpoint of ensuring that the first separation region V1 or the second separation region V2 is formed at positions other than around the separation start portion M serving as the separation start point in the process St4. The lower limit of the angle ϕ2 is not particularly limited, but can be equal to or greater than 10 degrees.

### (Fifth Pattern)

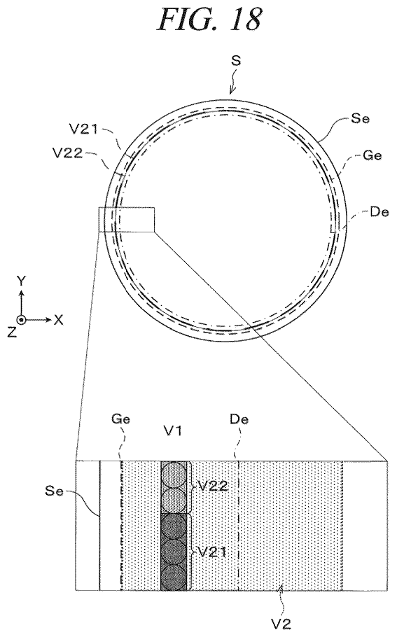

In a second pattern according to another exemplary embodiment, the infrared light Lir having the first intensity is radiated to a plurality of first positions spaced apart from each other by a predetermined distance in the circumferential direction of the adhesive G, and a first separation region V21 is formed as shown in FIG. 18. Also, the infrared light Lir having the second intensity smaller than the first intensity is radiated to second positions different from the first positions, and a first separation region V22 is formed. In the present exemplary embodiment, the first positions and the second positions are sequentially alternated in the circumferential direction of the adhesive G. Therefore, the first separation region V21 and the other first separation region V22 are alternately and sequentially formed.

According to the fifth pattern, the infrared light Lir is not radiated to a predetermined portion, and, thus, the processing time of the laser radiation device 32 is shortened. Also, it is possible to suppress the wear of the equipment, such as the laser head 110, caused by the radiation of the infrared light Lir and reduce energy consumption. Therefore, it is possible to reduce costs. Further, it is possible to suppress damage to the combined wafer T caused by the radiation of the infrared light Lir. The second intensity can be determined from the viewpoint of suppressing the wear of the equipment, such as the laser head 110, reducing energy consumption, and reducing costs.

### (Sixth Pattern)

In a sixth pattern according to another exemplary embodiment, the separation start portion M serving as the separation start point for the separating device 33 in the process St4 is previously determined as shown in FIG. 19. Further, the infrared light Lir is radiated to a plurality of positions in the radial direction where the central angle at the center C of the second wafer S is equal to an angle ϕ3 on both sides of the determined separation start portion M. In the present exemplary embodiment, the infrared light Lir is radiated several times to positions in a circular arc of the concentric circle with respect to the adhesive G where the central angle is equal to the angle ϕ3 on both sides of the separation start portion M along circular arcs of a plurality of concentric circles which is slightly different in diameter from each other. Thus, the first separation region V1 is continuously formed. In the present exemplary embodiment, the angle ϕ3 is 20 degrees.

The sixth pattern ensures that the first separation region V1 or the second separation region V2 is formed in the separation start portion M serving as the separation start point in the process St4. Since the first separation regions V1 overlap in the separation start portion M, it is possible to further reduce the adhesiveness of the adhesive G in the separation start portion M. Thus, it is possible to reduce the blade force. A part of the first separation region V1 and the second separation region V2 can be used as the separation start portion M2 in the separating method according to another exemplary embodiment to be described later. Also, the infrared light Lir is radiated only to a part of the entire circumference of the adhesive G, and, thus, it is possible to suppress the wear of the equipment, such as the laser head 110, caused by the radiation of the infrared light Lir and reduce energy consumption. Therefore, it is possible to reduce costs. Further, it is possible to suppress damage to the combined wafer T caused by the radiation of the infrared light Lir.

The upper limit of the angle ϕ3 is not particularly limited, but can be equal to or smaller than 90 degrees from the viewpoint of reduction in costs and suppression of damage to the combined wafer T. The lower limit of the angle ϕ3 is not particularly limited, but can be equal to or greater than 10 degrees from the viewpoint of reduction in blade force.

### (Seventh Pattern)

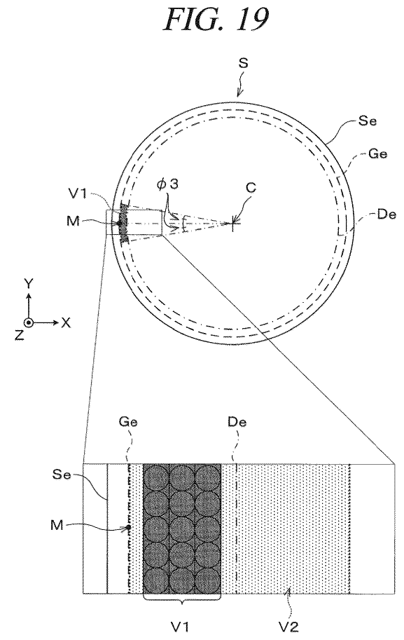

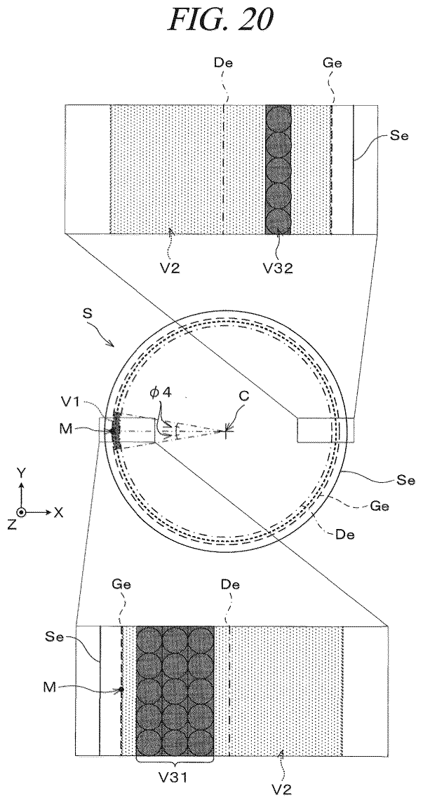

In a seventh pattern according to another exemplary embodiment, the separation start portion M serving as the separation start point for the separating device 33 in the process St4 is previously determined as shown in FIG. 20. Further, the infrared light Lir is radiated to a plurality of positions in the radial direction where the central angle at the center C of the second wafer S is equal to an angle ϕ4 on both sides of the determined separation start portion M, and a first separation region V31 is formed. The first separation region V31 and the angle ϕ4 are the same as the first separation region V1 and the angle ϕ3 in the sixth pattern. Also, the infrared light Lir is radiated concentrically with respect to the adhesive G to the entire circumference of the adhesive G in the circumferential direction, and another first separation region V32 is formed. The other first separation region V32 is the same as the exemplary embodiment described above with reference to FIG. 10.

The seventh pattern ensures that the first separation region V1 or the second separation region V2 is formed in the separation start portion M serving as the separation start point in the process St4. Since the first separation regions V1 overlap in the separation start portion M, it is possible to further reduce the adhesiveness of the adhesive G in the separation start portion M. A part of the first separation region V1 and the second separation region V2 can be used as the separation start portion M2 in the separating method according to another exemplary embodiment to be described later. Since the other first separation region V32 is formed along the entire circumference in the circumferential direction of the adhesive G, the adhesiveness of the adhesive G to the entire surface can be reduced. Therefore, it is possible to reduce the peeling force in the process St4.

### (Eighth Pattern)

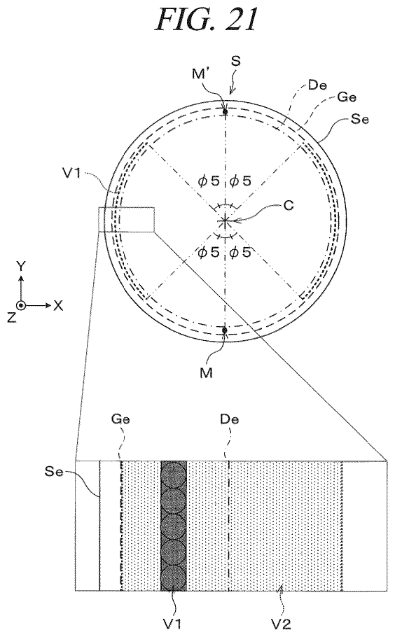

In an eighth pattern according to another exemplary embodiment, the separation start portion M serving as the separation start point for the separating device 33 in the process St4 is previously determined as shown in FIG. 21. Further, the infrared light Lir is radiated to positions in a circular arc of the concentric circle with respect to the adhesive G except a circular arc where the central angle at the center C of the second wafer S is equal to an angle ϕ5 on both sides of the determined separation start portion M. Furthermore, the infrared light Lir is radiated to positions in a circular arc except a circular arc where the central angle at the center C of the second wafer S is equal to the angle ϕ5 on both sides of a point M′ facing the separation start portion M across the center C of the second wafer S. In the present exemplary embodiment, the angle ϕ5 is 45 degrees.

The eighth pattern ensures that the first separation region V1 or the second separation region V2 is not only formed around the separation start portion M serving as the separation start point in the process St4, but formed at other positions. Thus, it is possible to reduce the peeling force. The infrared light Lir is not radiated to a predetermined portion, and, thus, the processing time of the laser radiation device 32 is shortened. Also, it is possible to suppress the wear of the equipment, such as the laser head 110, caused by the radiation of the infrared light Lir and reduce energy consumption. Therefore, it is possible to reduce costs. Further, it is possible to suppress damage to the combined wafer T caused by the radiation of the infrared light Lir.

The upper limit of the angle ϕ5 is not particularly limited, but can be equal to or smaller than 30 degrees from the viewpoint of ensuring that the first separation region V1 or the second separation region V2 is formed at positions other than around the separation start portion M serving as the separation start point in the process St4. The lower limit of the angle ϕ5 is not particularly limited, but can be equal to or greater than 10 degrees from the viewpoint of reduction in costs.

### (Ninth Pattern)

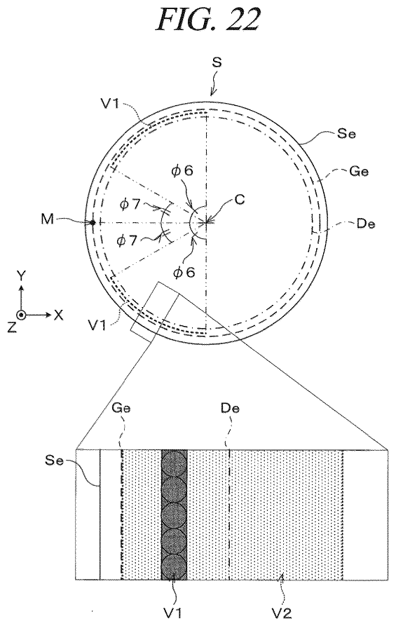

In a ninth pattern according to another exemplary embodiment, the separation start portion M serving as the separation start point for the separating device 33 in the process St4 is previously determined as shown in FIG. 22. Further, the infrared light Lir is radiated to positions in a circular arc of the concentric circle with respect to the adhesive G where the central angle at the center C of the second wafer S is equal to an angle ϕ6 on both sides of the determined separation start portion M except a circular arc where the central angle at the center C is equal to an angle ϕ7 on both sides of the separation start portion M. In the present exemplary embodiment, the angle ϕ6 is 90 degrees. Also, in the present exemplary embodiment, the angle ϕ7 is 30 degrees.

As a result of the earnest research conducted by the present inventors, it was found that the load applied to the second wafer S is greatest at a position where the first separation region V1 is formed in the ninth pattern shown in FIG. 22 when the suction device 132 is raised in the separating device 33. The load applied to the second wafer S refers to a stress applied to the second wafer S when the second wafer S is separated from the separation start portion M in the direction from the one end S1 toward the other end S2 as shown in FIG. 13A to FIG. 13C. When the load reaches a predetermined level, the second wafer S may be cracked.

In this regard, according to the ninth pattern, the first separation region V1 is formed at a position where the load applied to the second wafer S is greatest, and, thus, the load applied to the second wafer S can be reduced. Therefore, it is possible to suppress cracks in the second wafer S. Also, it is possible to reduce the peeling force. The infrared light Lir is not radiated to a predetermined portion, and, thus, the processing time of the laser radiation device 32 is shortened. Also, it is possible to suppress the wear of the equipment, such as the laser head 110, caused by the radiation of the infrared light Lir and reduce energy consumption. Therefore, it is possible to reduce costs. Further, it is possible to suppress damage to the combined wafer T caused by the radiation of the infrared light Lir.

### (Tenth Pattern)

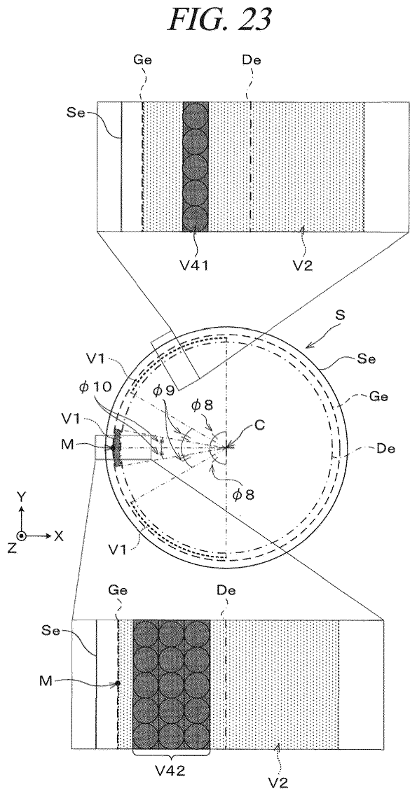

In a tenth pattern according to another exemplary embodiment, the separation start portion M serving as the separation start point for the separating device 33 in the process St4 is previously determined as shown in FIG. 23. Further, the infrared light Lir is radiated to positions in a circular arc of the concentric circle with respect to the adhesive G where the central angle at the center C of the second wafer S is equal to an angle ϕ8 on both sides of the determined separation start portion M except a circular arc where the central angle at the center C is equal to an angle ϕ9 on both sides of the separation start portion M, and a first separation region V41 is formed. The first separation region V41 is the same as the first separation region V1 in the ninth pattern. The angle ϕ8 is the same as the angle ϕ6 in the ninth pattern, and the angle ϕ9 is the same as the angle ϕ7 in the ninth pattern. Furthermore, the infrared light Lir is radiated to a plurality of positions in the radial direction where the central angle at the center C of the second wafer S is equal to an angle ϕ10 on both sides of the separation start portion M, and another first separation region V42 is formed. The other first separation region V42 and the angle ϕ10 are the same as the first separation region V1 and the angle ϕ3 in the sixth pattern.

In the tenth pattern, as in the ninth pattern, the first separation region V1 is formed at a position where the load applied to the second wafer S is greatest, and, thus, the load applied to the second wafer S can be reduced. Therefore, it is possible to suppress the cracks in the second wafer S. Also, it is possible to reduce the peeling force. As in the sixth pattern, the tenth pattern ensures that the first separation region V1 or the second separation region V2 is formed in the separation start portion M serving as the separation start point in the process St4. Since the first separation regions V1 overlap in the separation start portion M, it is possible to further reduce the adhesiveness of the adhesive G in the separation start portion M. Thus, it is possible to reduce the blade force. Also, the infrared light Lir is not radiated to a predetermined portion, and, thus, the processing time of the laser radiation device 32 is shortened. Further, it is possible to suppress the wear of the equipment, such as the laser head 110, caused by the radiation of the infrared light Lir and reduce energy consumption. Therefore, it is possible to reduce costs. Furthermore, it is possible to suppress damage to the combined wafer T caused by the radiation of the infrared light Lir.

### OTHER EXEMPLARY EMBODIMENTS OF SEPARATING METHOD

In the separating device 33 according to the above-described exemplary embodiments, the separation start portion M serving as the separation start point is formed by allowing the blade 140 to be inserted into and penetrate through the interface B between the adhesive G and the second wafer S in which the first separation region V1 or the second separation region V2 is formed. In this regard, in an exemplary embodiment, a part of the first separation region V1 or the second separation region V2 formed in the adhesive G by radiating the infrared light Lir according to the exemplary embodiment is determined as the separation start portion M2 which is a separation start point. That is, in the separating device 33, the process of inserting the blade 140 may be omitted. More specifically, after the separation start portion M2 is determined, the suction device 132 on the one end S1′ side is raised as shown in FIG. 13B. Then, the second wafer S is separated from the separation start portion M in the direction from the one end S1 toward the other end S2. Thereafter, as shown in FIG. 13C, the suction device 132 on the other end S2's side is raised to separate the entire surface of the second wafer S from the first wafer W.

In the separating method according to the other exemplary embodiment, the separating device 33 may not be equipped with the blade 140 and the moving mechanism. Since the process of inserting the blade 140 can be omitted, the processing time of the separating device 33 can be shortened.

The separating device 33 according to the above-described exemplary embodiments raises the suction device 132 to separate the second wafer S from the first wafer W in a direction to one end to the other end from the separation start portion M. In this regard, the separating device 33 may inject a gas between the first wafer W and the second wafer S to facilitate the separation between the first wafer W and the second wafer S.

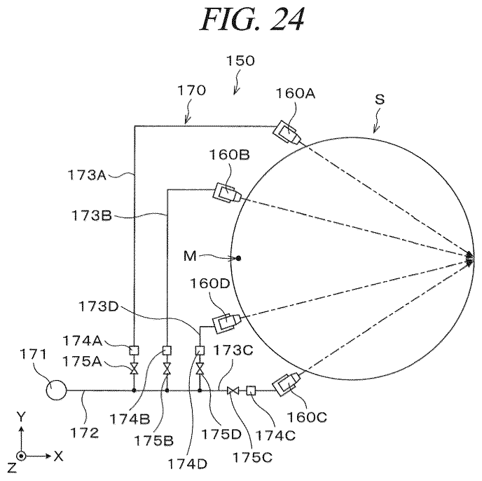

As shown in FIG. 24, the separating device 33 is equipped with a gas injection device 150 configured to inject a gas, e.g., air, between the first wafer W and the second wafer S. The gas injection device 150 is equipped with a nozzle 160 configured to inject air toward the combined wafer T and a gas supply 170 configured to supply the air to the nozzle 160. Also, the gas injected by the gas injection device 150 is not limited to air, and may be an inert gas, such as an argon gas and a nitrogen gas. Further, it is desirable that the gas is injected from the gas injection device 150 at a high pressure.

A plurality of, for example, four nozzles 160 is provided on a side portion of the combined wafer T held by the first holder 120. For example, two 160A and 160B of the four nozzles 160 are placed in the positive Y-axis direction with respect to the separation start portion M, and the other two nozzles 160C and 160D are placed in the positive Y-axis direction with respect to the separation start portion M. Also, the nozzles 160A and 160B and the nozzles 160C and 160D are disposed symmetrically to each other, with respect to the separation start portion M, and the nozzles 160A and 160C are placed in the positive X-axis direction compared to the nozzles 160B and 160D, respectively. Further, the number and the layout of nozzles 160 are not limited to the example of the present exemplary embodiment, but can be arbitrarily determined.

The nozzles 160A to 160D are disposed at a height position corresponding to an outer end of the combined wafer T, and disposed at the same height position. Also, the nozzles 160A to 160D may be configured to be movable in the vertical direction by an elevating mechanism (not shown).

Air injection holes (not shown) of the nozzles 160A to 160D are wide in the horizontal direction, and the nozzles 160A to 160D inject the air in the horizontal direction. Also, the air from the nozzles 160A to 160D may injected at a wide angle. Air injection directions of the nozzles 160A to 160D are set to positions facing the separation start portion M across the center of the combined wafer T (positions in the positive X-axis direction). That is, the nozzles 160A to 160D are different in the air injection direction from each other, and the gas injection device 150 may switch between the plurality of nozzles 160A to 160D and change the air injection directions while injecting the air.

The gas supply 170 is equipped with a gas source 171, a main line 172, branch lines 173A to 173D, flow rate regulators 174A to 174D, and opening/closing valves 175A to 175D.

The gas source 171 reserves the air therein and supplies the air to the nozzles 160A to 160D. In the present exemplary embodiment, the gas source 171 is provided in common for the nozzles 160A to 160D, but the number of gas sources 171 is not limited thereto. For example, two gas sources 171 may be provided, and one of the gas sources 171 may supply the air to the nozzles 160A and 160B, and the other gas source 171 may supply the air to the nozzles 160C and 160D. Alternatively, four gas sources 171 may individually supply the air to the nozzles 160A to 160D.

The main line 172 is connected to the gas source 171, distributes the air from the gas source 171, and supplies the air to the branch lines 173A to 173D. The branch lines 173A to 173D are branched from the main line 172 to be connected to the nozzles 160A to 160D. The branch lines 173A to 173D distribute the air from the main line 172 and supply the air to the nozzles 160A to 160D.

The flow rate regulators 174A to 174D and the opening/closing valves 175A to 175D are provided in the branch lines 173A to 173D, respectively. For example, mass flow controllers are used as the flow rate regulators 174A to 174D configured to regulate the flow rates of the air flowing through the branch lines 173A to 173D and control the amounts of the air injected by the nozzles 160A to 160D. The nozzles 160A to 160D configured to inject the air can be switched by switching the opening and closing of the opening/closing valves 175A to 175D.

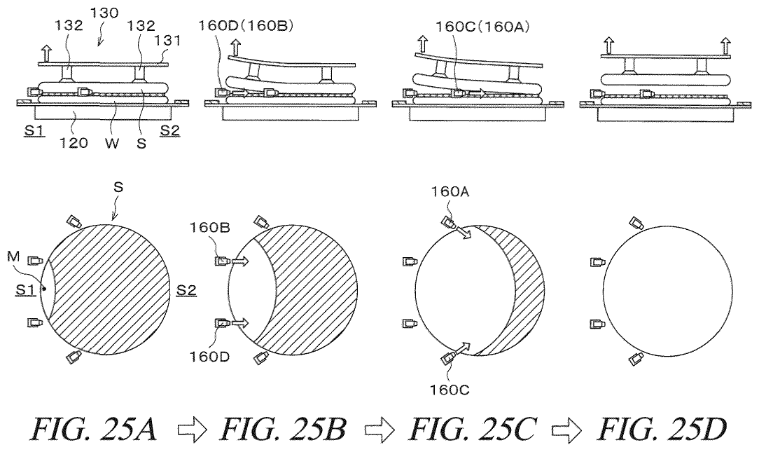

Hereinafter, the separating processing to be performed by the separating device 33 equipped with the gas injection device 150 configured as described above will be described. FIG. 25A to FIG. 25D are diagrams illustrating a state in which the first wafer W and the second wafer S are separated from each other according to the present exemplary embodiment. In the combined wafer T, the areas where the first wafer W and the second wafer S are bonded to each other are indicated with hatching in FIG. 25A to FIG. 25D.

In the separating processing according to the present exemplary embodiment, the separation start portion M serving as the separation start point is formed by allowing the blade 140 to be inserted into and penetrate through the interface B between the adhesive G and the second wafer S, as shown in FIG. 25A. Alternatively, the separation start portion M may be formed by radiating the infrared light Lir as described above.

Then, as shown in FIG. 25B, the suction device 132 on the one end S1's side is raised, and the air is injected between the second wafer S and the adhesive G in the horizontal direction from the nozzles 160B and 160D. In this case, the air is injected only from the nozzles 160B and 160D by opening the opening/closing valves 175B and 175D and closing the opening/closing valves 175A and 175C. Also, the injection of air from the nozzles 160B and 160D starts at the same time or before the suction device 132 is raised. Then, the second wafer S is separated from the separation start portion M in the direction from the one end S1 to the other end S2.

Thereafter, as shown in FIG. 25C, when the second wafer S is separated toward the other end S2, the air is injected between the second wafer S and the adhesive G in the horizontal direction from the nozzles 160A and 160C. In this case, the air is injected only from the nozzles 160A and 160C by opening the opening/closing valves 175A and 175C and closing the opening/closing valves 175B and 175D. The switching timing of the opening/closing valves 175A to 175D is set based on the separation state of the second wafer S. For example, the switching timing may be previously set by experiment, or may be set in real time by detecting the separation state of the second wafer S. Although the injection of air from the nozzles 160B and 160D is stopped in the present exemplary embodiment, the air may continue to be injected from the nozzles 160B and 160D.

Thereafter, as shown in FIG. 25D, the suction device 132 on the other end S2's side is raised, and the entire surface of the second wafer S is separated from the first wafer W. In this case, the injection of air from the nozzles 160A and 160C is stopped by closing the opening/closing valves 175A and 175C.

According to the present exemplary embodiment as described above, the suction device 132 is raised and the air is injected between the first wafer W and the second wafer S from the gas injection device 150. Thus, the first wafer W and the second wafer S can be separated from each other quickly and efficiently. Also, the separation between the first wafer W and the second wafer S can be performed more efficiently by switching the injection of air from the nozzles 160A to 160D based on the separation state of the second wafer S.

Also, the stress onto the second wafer S caused by raising the suction device 132 can be reduced, and, thus, it is possible to suppress damage to the second wafer S. Further, the first wafer W is pressed against the first holder 120 by the air, and, thus, it is also possible to suppress damage to the first wafer W. Therefore, it is possible to improve the throughput of the entire separating processing.

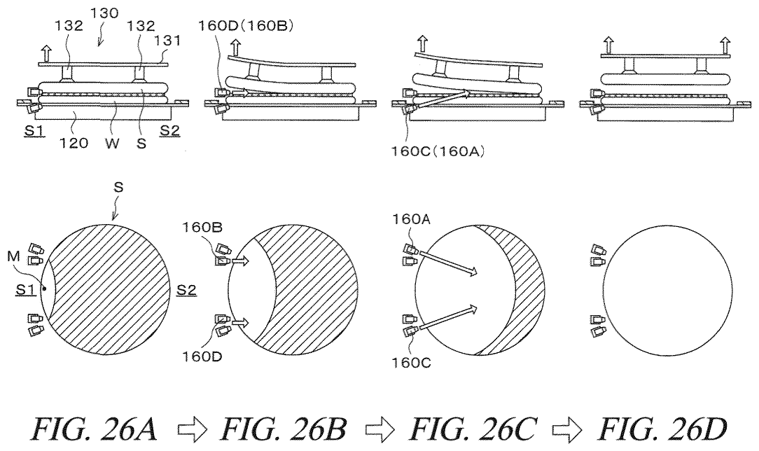

Furthermore, in the present exemplary embodiment, the number and the layout of nozzles 160 can be arbitrarily determined as described above. For example, a plurality of nozzles 160 may be located at different heights. As shown in FIG. 26A to FIG. 26D, the nozzle 160A may be placed at a position adjacent to the nozzle 160B and vertically below the nozzle 160B when viewed from the top. Likewise, the nozzle 160C may be placed at a position adjacent to the nozzle 160D and vertically below the nozzle 160D when viewed from the top. Also, unlike the above-described exemplary embodiment, the nozzles 160A and 160D inject the air diagonally upwards in the vertical direction.

In this case, the separation start portion M serving as the separation start point is formed as shown in FIG. 26A, the suction device 132 on the one end S1's side is raised as shown in FIG. 26B, and the air is injected between the second wafer S and the adhesive G in the horizontal direction from the nozzles 160B and 160D. Herein, the air is injected from the nozzles 160B and 160D in the same manner as shown in FIG. 25B.

Thereafter, when the second wafer S is separated toward the other end S2 as shown in FIG. 26C, the air is injected between the second wafer S and the adhesive G from the nozzles 160A and 160C. In this case, the nozzles 160A and 160C inject the air diagonally upwards in the vertical direction. Then, the second wafer S is pushed upwards by the injected air, which facilitates the separation of the second wafer S. Therefore, the second wafer S can be separated quickly. Further, the suction device 132 on the other end S2's side is raised as shown in FIG. 26D, and the entire surface of the second wafer S is separated from the first wafer W.

Also, in the present exemplary embodiment, if the nozzle 160 is configured to be movable in the vertical direction as described above, the nozzle 160 may reciprocate in the vertical direction when the air is injected between the second wafer S and the adhesive G from the nozzle 160. In this case, the air injected between the second wafer S and the adhesive G varies in intensity in the vertical direction and over time. That is, the air may be injected to various positions between the second wafer S and the adhesive G. Since the air more smoothly flows into a narrow gap between the adhesive G and the second wafer S being separated, it is possible to quickly widen the gap. Therefore, the gas injection device 150 can separate the second wafer S quickly by injecting the air.

Further, in the present exemplary embodiment, the nozzle 160 may be configured to be movable in the horizontal direction by a horizontal moving mechanism (not shown). For example, the nozzle 160 may be configured to be movable along the outer circumference of the combined wafer T when viewed from the top. In this case, the nozzle 160 may be placed depending on the separation state of the second wafer S, i.e., the separation position of the second wafer S between the one end S1 and the other end S2. For example, a position of the nozzle 160 may be previously set by experiment, or may be set in real time by detecting the separation state of the second wafer S. As such, the separation between the first wafer W and the second wafer S can be performed efficiently by moving the injection position of the air from the nozzle 160 in the horizontal direction based on the separation state of the second wafer S.

### OTHER EMBODIMENTS

In the above-described exemplary embodiments, the second wafer S and the adhesive G are separated in the combined wafer T in which the first wafer W and the second wafer S are bonded to each other. However, the present disclosure is not limited thereto. For example, the device layer D instead of the first wafer W is directly fixed to the dicing frame F via the dicing tape P. In this case, the device layer D is bonded to the second wafer S via the adhesive G, and, thus, the device layer D and the second wafer S form the combined structure according to the present disclosure.

Also, in the above-described exemplary embodiments, the second wafer S is separated from the first wafer W. However, the present disclosure is not limited thereto. For example, the first wafer W may be separated from the second wafer S, or in a combined wafer T in which two first wafers W are bonded to each other, one of the first wafers W may be separated from the other first wafer W. If a back-grind tape instead of the second wafer S serves as the second substrate according to the present disclosure and is bonded to the first wafer W via the adhesive G, the back-grind tape may be separated from the first wafer W.

Further, in the above-described exemplary embodiments, the infrared light Lir is radiated concentrically with respect to the adhesive G at the plurality of positions in the radial direction. However, the infrared light Lir may be radiated in a spiral shape concentric with respect to the adhesive G.

In the above-described exemplary embodiments, the adhesive G is used as the adhesive layer configured to bond the first wafer W and the second wafer S. However, for example, an adhesive tape may be used.

The embodiments disclosed herein are illustrative in all aspects and do not limit the present disclosure. Further, the above-described embodiments may be omitted, substituted, or changed in various forms without departing from the scope and spirit of the appended claims. For example, the constituent elements of the above-described exemplary embodiments may be combined in various ways. From any of these various combinations, functions and effects for the respective constituent elements are naturally obtained, and other functions and other effects obvious to those skilled in the art are also obtained from the description of the present specification.

According to the exemplary embodiment, it is possible to efficiently separate the second substrate from the combined structure in which the first substrate and the second substrate are bonded to each other via the adhesive layer.

From the foregoing, it will be appreciated that various exemplary embodiments of the present disclosure have been described herein for purposes of illustration and various changes can be made without departing from the scope and spirit of the present disclosure. Accordingly, various exemplary embodiments described herein are not intended to be limiting, and the true scope and spirit are indicated by the following claims.

We claim:

1. A method of separating a second substrate from a combined structure in which a first substrate and the second substrate are bonded to each other via an adhesive layer, the second substrate is configured to allow light to pass therethrough, and the adhesive layer is degraded by absorbing the light, the method comprising:
radiating the light to the adhesive layer via the second substrate to form, at an interface between the adhesive layer and the second substrate, a first separation region by degrading the adhesive layer that absorbs the light and a second separation region extending from the first separation region at least in a radial direction of the adhesive layer; and
separating the second substrate from the combined structure.

2. The separating method of claim 1, wherein
in the radiating of the light to the adhesive layer,
the first separation region is formed by radiating the light to a position inwardly spaced apart from a peripheral edge of the adhesive layer in the radial direction, and
the second separation region is formed to extend from the first separation region to the peripheral edge of the adhesive layer.

3. The separating method of claim 2, wherein
in the second separation region extending from the first separation region to the peripheral edge of the adhesive layer, a width in the radial direction is previously determined such that a by-product, which is generated when the adhesive layer is degraded by absorbing the light radiated to the adhesive layer, does not flow out of the peripheral edge of the adhesive layer.

4. The separating method of claim 1, wherein
a device layer is formed on a front surface of the first substrate, and
in the radiating of the light to the adhesive layer, the first separation region is formed by radiating the light to the adhesive layer outside a peripheral edge of the device layer in the radial direction when viewed from the top, and
the second separation region is formed to extend to a position overlapping the device layer when viewed from the top.

5. The separating method of claim 1, wherein
a device layer is formed on a front surface of the first substrate, and
in the radiating of the light to the adhesive layer, the light is radiated to the adhesive layer at a position overlapping the device layer when viewed from the top.

6. The separating method of claim 1, wherein
a device layer is formed on a front surface of the first substrate, and
in the radiating of the light to the adhesive layer,
the light having a first intensity is radiated, concentrically with respect to the adhesive layer, to the adhesive layer outside a peripheral edge of the device layer in the radial direction when viewed from the top, and
the light having a second intensity smaller than the first intensity is radiated, concentrically with respect to the adhesive layer, to the adhesive layer at a position overlapping the device layer when viewed from the top.

7. The separating method of claim 1, wherein
in the radiating of the light to the adhesive layer, the light is radiated to multiple positions spaced apart from each other in a circumferential direction of the adhesive layer.

8. The separating method of claim 7, wherein
in the radiating of the light to the adhesive layer,
the light having a first intensity is radiated to multiple first positions spaced apart from each other in the circumferential direction of the adhesive layer, and
the light having a second intensity smaller than the first intensity is radiated to multiple second positions different from the first positions.

9. The separating method of claim 2, wherein
in the separating of the second substrate from the combined structure, a force to be applied in a direction of separating the second substrate from the combined structure is applied toward an inside of the adhesive layer in the radial direction from a start point, which is a part of the peripheral edge of the adhesive layer where the first separation region or the second separation region is formed.

10. The separating method of claim 9, wherein
in the separating of the second substrate from the combined structure, a blade is inserted into the start point in the peripheral edge of the adhesive layer.

11. The separating method of claim 9, wherein
in the radiating of the light to the adhesive layer, the light is radiated to positions in a circular arc of a concentric circle with respect to the adhesive layer where a central angle on both sides of the start point is equal to or smaller than 90 degrees.

12. The separating method of claim 10, wherein
in the radiating of the light to the adhesive layer, the light is radiated to positions in a circular arc of a concentric circle with respect to the adhesive layer except a circular arc where a central angle on both sides of the start point is from 10 degrees to 30 degrees.

13. The separating method of claim 10, wherein
in the radiating of the light to the adhesive layer, the light is radiated to positions in a circular arc of a concentric circle with respect to the adhesive layer except a circular arc where a central angle on both sides of the start point is equal to or smaller than 45 degrees and a circular arc where a central angle on both sides of a point facing the start point across a center of the second substrate is equal to or smaller than 45 degrees.

14. The separating method of claim 9, wherein
in the radiating of the light to the adhesive layer, the light is radiated to multiple positions in the radial direction in a circular arc of a concentric circle with respect to the adhesive layer where a central angle on both sides of the start point is equal to or greater than 10 degrees.

15. The separating method of claim 9, wherein
in the radiating of the light to the adhesive layer,
the light is radiated to an entire circumference of a concentric circle with respect to the adhesive layer, and
the light is radiated to multiple positions in the radial direction in the adhesive layer where a central angle on both sides of the start point is equal to or greater than 10 degrees.

16. The separating method of claim 9, wherein
in the radiating of the light to the adhesive layer, the light is radiated to positions in a circular arc of a concentric circle with respect to the adhesive layer where a central angle on both sides of the start point is equal to or smaller than 90 degrees except a circular arc where the central angle on both sides of the start point is from 10 degrees to 30 degrees.

17. The separating method of claim 1, wherein
in the separating of the second substrate from the combined structure, a gas is injected between the first substrate and the second substrate.

18. A system configured to separate a second substrate from a combined structure in which a first substrate and the second substrate are bonded to each other via an adhesive layer, the second substrate is configured to allow light to pass therethrough, and the adhesive layer is degraded by absorbing the light, the system comprising:
a laser radiation device configured to radiate the light to the combined structure;
a separating device configured to separate the second substrate from the combined structure to which the light is radiated; and
circuitry configured to:
control the laser radiation device to radiate the light to the adhesive layer via the second substrate to form, at an interface between the adhesive layer and the second substrate, a first separation region by degrading the adhesive layer that absorbs the light and a second separation region extending from the first separation region at least in a radial direction of the adhesive layer; and
control the separating device to separate the second substrate from the combined structure by applying a force to the combined structure to which the light is radiated.

19. The separating system of claim 18, wherein
in the radiating of the light to the adhesive layer, the circuitry is configured to:
control the laser radiation device to form the first separation region by radiating the light to a position inwardly spaced apart from a peripheral edge of the adhesive layer in the radial direction; and
control the laser radiation device to form the second separation region to extend from the first separation region to the peripheral edge of the adhesive layer.

20. The separating system of claim 19, wherein
in the second separation region extending from the first separation region to the peripheral edge of the adhesive layer, a width in the radial direction is previously determined such that a by-product, which is generated when the adhesive layer is degraded by absorbing the light radiated to the adhesive layer, is not generated outside the peripheral edge of the adhesive layer.
